(19) United States
(12) Patent Application Publication
(10) Pub. No.: US 2025/0378882 A1
(43) Pub. Date: Dec. 11, 2025

(54) NON-VOLATILE MEMORY DEVICE INCLUDING CELL STRING, STORAGE DEVICE INCLUDING THE SAME, AND METHOD OF OPERATING THE SAME

(71) Applicant: Samsung Electronics Co., Ltd., Suwon-si (KR)

(72) Inventors: GILSUNG LEE, Suwon-si (KR); SEUNG-JUN LEE, Suwon-si (KR)

(21) Appl. No.: 19/051,115

(22) Filed: Feb. 11, 2025

(30) Foreign Application Priority Data
Jun. 11, 2024 (KR) 10-2024-0075764

(51) Int. Cl. G11C 16/10; G11C 16/04; G11C 16/28

(52) U.S. Cl. CPC G11C 16/102; G11C 16/0483; G11C 16/28

(57) ABSTRACT

A method of operating a non-volatile memory device which includes a cell string includes performing a programming operation on a first string selection transistor of the cell string, performing a first read operation on the first string selection transistor based on a first reference voltage, and performing a programming operation on a second string selection transistor of the cell string connected to the first string selection transistor to have: a first target threshold voltage level in response to that a first bit value obtained by the first read operation indicates a first logical value, and a second target threshold voltage level lower than the first target threshold voltage level in response to that the first bit value indicates a second logical value opposite to the first logical value.

### CROSS-REFERENCE TO RELATED APPLICATION(S)

This application claims priority under 35 U.S.C. § 119 to Korean Patent Application No. 10-2024-0075764 filed on Jun. 11, 2024, in the Korean Intellectual Property Office, the disclosures of which are incorporated by reference herein in their entireties.

### BACKGROUND

Embodiments of the present disclosure described herein relate to a semiconductor device, and more particularly, relate to a non-volatile memory device includes a cell string, a storage device including the same, and a method of operating the same.

A memory device stores data in response to a write request and outputs data stored therein in response to a read request. For example, the memory device is classified as a volatile memory device, which loses data stored therein when a power is turned off, such as a dynamic random access memory (DRAM) device or a static RAM (SRAM) device, or a non-volatile memory device, which retains data stored therein even when a power is turned off, such as a flash memory device, a phase-change RAM (PRAM), a magnetic RAM (MRAM), or a resistive RAM (RRAM).

The non-volatile memory device may be used in a storage device storing a large amount of data. The non-volatile memory device may include a cell string. The cell string may include a plurality of transistors connected in series. Some of the plurality of transistors may be used as a string selection transistor. The corresponding cell string may be selected or may not be selected by controlling the string selection transistor. In order to realize high performance and high reliability of the non-volatile memory device, research and development of non-volatile memory device having a cell string which includes the string selection transistor to improve a voltage margin of the string selection transistor are continuously being conducted.

### SUMMARY

Embodiments of the present disclosure provide a non-volatile memory device includes a cell string, a storage device including the same, and a method of operating the same.

According to an embodiment, a method of operating a non-volatile memory device which includes a first cell string includes performing a programming operation on a first string selection transistor of the first cell string, performing a first read operation on the first string selection transistor based on a first reference voltage, performing a programming operation on a second string selection transistor of the first cell string connected to the first string selection transistor to have: a first target threshold voltage level in response to that a first bit value obtained by the first read operation indicates a first logical value, and a second target threshold voltage level lower than the first target threshold voltage level in response to that the first bit value indicates a second logical value opposite to the first logical value.

According to an embodiment, a non-volatile memory device includes a cell string that includes a first string selection transistor and a second string selection transistor connected in series, a voltage generating circuit that is connected to the first string selection transistor through a first string selection line and is connected to the second string selection transistor through a second string selection line, a page buffer circuit that is connected to the cell string through a bit line, and a threshold voltage level management circuit. The threshold voltage level management circuit provides a first programming voltage to the first string selection transistor through the voltage generation circuit, provides a reference voltage to the first string selection transistor through the voltage generation circuit, receives a bit value of the first string selection transistor corresponding to the reference voltage from the page buffer circuit, provides a second programming voltage to the second string selection transistor through the voltage generation circuit in response to that the bit value indicates a first logical value, and provides a third programming voltage lower than the second programming voltage to the second string selection transistor through the voltage generation circuit in response to that the bit value indicates a second logical value opposite to the first logical value.

According to an embodiment, a storage device includes a storage controller that generates voltage level information including a reference voltage, a first programming voltage, a second programming voltage, and a third programming voltage, and a non-volatile memory device. The non-volatile memory device including a first cell string receives the voltage level information from the storage controller, performs a programming operation on a first string selection transistor of the first cell string, based on the first programming voltage, performs a read operation on the first string selection transistor, based on the reference voltage, and performs a programming operation on a second string selection transistor of the first cell string to have: a first target threshold voltage level in response to that a bit value obtained by the read operation indicates a first logical value, based on the second programming voltage, and a second target threshold voltage level lower than the first target threshold voltage level in response to that the bit value indicates a second logical value opposite to the first logical value, based on the third programming voltage.

### BRIEF DESCRIPTION OF THE FIGURES

The above and other objects and features of the present disclosure will become apparent by describing in detail embodiments thereof with reference to the accompanying drawings.

FIG. 1 is a block diagram of an electronic device according to an embodiment of the present disclosure.

FIG. 2 is a block diagram illustrating a storage controller of FIG. 1, according to some embodiments of the present disclosure.

FIG. 3 is a block diagram illustrating a non-volatile memory device of FIG. 1, according to some embodiments of the present disclosure.

FIG. 4 is a diagram describing a memory block of FIG. 3, according to some embodiments of the present disclosure.

FIG. 5 is a diagram describing a memory block to some embodiments of the present disclosure.

FIG. 6 is a diagram describing trim schemes according to some embodiments of the present disclosure.

FIG. 7 is a diagram describing simulations of a counter trim scheme according to some embodiments of the present disclosure.

FIG. 8 is a diagram describing a method of operating a non-volatile memory device according to some embodiments of the present disclosure.

FIG. 9 is a diagram describing a non-volatile memory device according to some embodiments of the present disclosure.

FIG. 10 is a diagram describing a merged counter trim operation according to some embodiments of the present disclosure.

FIG. 11 is a diagram describing continuous counter trim operations according to some embodiments of the present disclosure.

FIG. 12 is a diagram describing a fine counter trim operation according to some embodiments of the present disclosure.

FIG. 13 is a flowchart describing a method of operating a non-volatile memory device according to some embodiments of the present disclosure.

FIG. 14 is a flowchart describing a method of operating a non-volatile memory device according to some embodiments of the present disclosure.

FIG. 15 is a flowchart describing a method of operating a storage device according to some embodiments of the present disclosure.

### DETAILED DESCRIPTION

Below, embodiments of the present disclosure will be described in detail and clearly to such an extent that one skilled in the art carries out embodiments of the present disclosure easily.

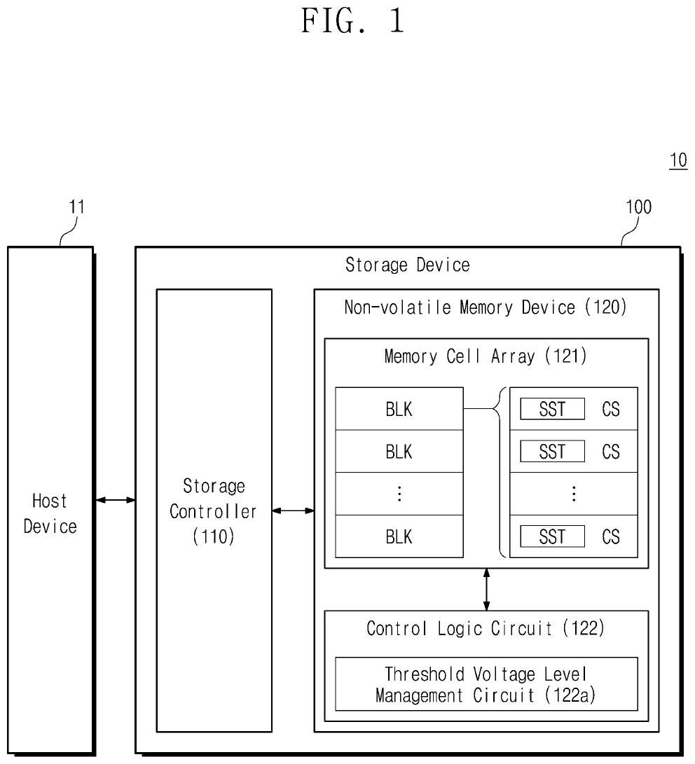

FIG. 1 is a block diagram of an electronic device according to an embodiment of the present disclosure. Referring to FIG. 1, an electronic device 10 may include a host device 11 and a storage device 100. The electronic device 10 may be a computing system, which is configured to process a variety of information, such as a personal computer (PC), a notebook, a laptop, a server, a workstation, a tablet PC, a smartphone, a digital camera, and a black box.

The host device 11 may control all the operations of the electronic device 10. For example, the host device 11 may store data in the storage device 100, may read data stored in the storage device 100, or may delete data stored in the storage device 100.

The storage device 100 may include a storage controller 110 and a non-volatile memory device 120. Under control of the host device 11 or depending on an algorithm of an internal firmware module, the storage controller 110 may store data in the non-volatile memory device 120, may read the stored data from the non-volatile memory device 120, or may delete the stored data.

For example, based on a command indicating an operation (e.g., a program operation, a read operation, or an erase operation) to be performed for the non-volatile memory device 120 and an address indicating a location of data, the storage controller 110 may store the data in the non-volatile memory device 120, may read the data stored in the non-volatile memory device 120, or may delete the data stored in the non-volatile memory device 120.

The non-volatile memory device 120 may store data under control of the storage controller 110. In some embodiments, the non-volatile memory device 120 may be a Not AND (NAND) flash memory. However, the present invention is not limited thereto. For the non-volatile memory device 120 may be implemented with one of various storage devices, which are able to retain data stored therein even though a power is turned off, such as a phase-change random access memory (PRAM), a magnetic random access memory (MRAM), a resistive random access memory (RRAM), and a ferroelectric random access memory (FRAM).

The non-volatile memory device 120 may include a memory cell array 121 and a control logic circuit 122. The memory cell array 121 may include the plurality of memory blocks BLK. Each of the plurality of memory blocks BLK may include a plurality of cell strings CS. In the memory block BLK, the plurality of cell strings CS may share a bit line. Each of the cell strings CS may include transistors connected in series. Some of the transistors may be used as a string selection transistor SST. The others (or others) of the transistors may be used as a memory cell for storing data.

The string selection transistor SST may be used to select a corresponding cell string CS among the cell strings CS sharing the bit line. For example, the string selection transistor SST may have a threshold voltage level. When the corresponding cell string CS is selected, a turn-on voltage exceeding a threshold voltage level may be applied to a gate terminal of the string selection transistor SST, and the string selection transistor SST may connect the corresponding cell string CS to the bit line.

As another example, when the corresponding cell string CS is not selected (i.e., is unselected), a turn-off voltage not exceeding (or lower than) the threshold voltage level may be applied to the gate terminal of the string selection transistor SST, and the string selection transistor SST may disconnect (i.e., electrically disconnect) the corresponding cell string CS from the bit line.

The control logic circuit 122 may control all the operations of the non-volatile memory device 120. For example, based on the command and the address received from the storage controller 110, the control logic circuit 122 may store data in the memory cell array 121, may read the stored data, or may erase the stored data.

The control logic circuit 122 may include a threshold voltage level management circuit 122a. The threshold voltage level management circuit 122a may store voltage level information which is used to determine a programming voltage to be applied to the string selection transistors SST of the memory cell array 121. Based on the voltage level information, the threshold voltage level management circuit 122a may determine threshold voltage levels of the string selection transistors SST by applying the programming voltage to the string selection transistors SST of the memory cell array 121.

The threshold voltage level management circuit 122a may store the voltage level information which is determined in the process of manufacturing the non-volatile memory device 120. Alternatively, the storage controller 110 may update the voltage level information of the threshold voltage level management circuit 122a.

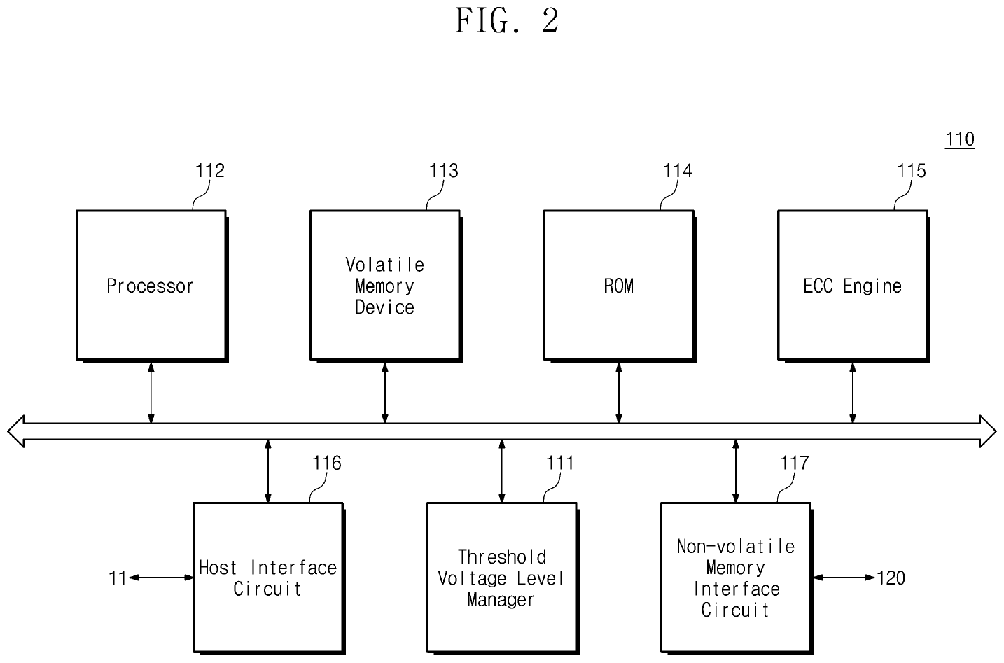

FIG. 2 is a block diagram illustrating a storage controller of FIG. 1, according to some embodiments of the present disclosure. Referring to FIGS. 1 and 2, the storage controller 110 may communicate with the host device 11 and the non-volatile memory device 120.

The storage controller 110 may include a threshold voltage level manager 111, a processor 112, a volatile memory device 113, a read only memory (ROM) 114, an error correcting code (ECC) engine 115, a host interface circuit 116, and a non-volatile memory interface circuit 117.

The threshold voltage level manager 111 may update the voltage level information stored in the threshold voltage level management circuit 122a of the non-volatile memory device 120. For example, the threshold voltage level manager 111 may optimize (or determine) the voltage level information based on at least one of a use time of the storage device 100, an operating temperature of the storage device 100, and a power mode of the storage device 100. The threshold voltage level manager 111 may provide the optimized (or determined) voltage level information to the threshold voltage level management circuit 122a. The threshold voltage level management circuit 122a may manage the threshold voltage level of the string selection transistors SST based on the optimized voltage level information.

The processor 112 may control all the operations of the storage controller 110. The volatile memory device 113 may be used as a main memory, a buffer memory, or a cache memory of the storage controller 110. The ROM 114 may store information to be used for the operation of the storage controller 110 in a read-only manner. The ECC engine 115 may detect and correct an error of data received from the non-volatile memory device 120.

The threshold voltage level manager 111 may be implemented by hardware, software, or a combination thereof. When at least some of functions of the threshold voltage level manager 111 are implemented by software, the processor 112 may implement at least some of the functions of the threshold voltage level manager 111 by loading instructions stored in the non-volatile memory device 120 to the volatile memory device 113 and executing the loaded instructions.

The storage controller 110 may communicate with the host device 11 through the host interface circuit 116. In some embodiments, the host interface circuit 116 may be implemented based on at least one of various interfaces such as a serial ATA (SATA) interface, a peripheral component interconnect express (PCIe) interface, a serial attached SCSI (SAS), a non-volatile memory express (NVMe) interface, and a universal flash storage (UFS) interface.

The storage controller 110 may communicate with the non-volatile memory device 120 through the non-volatile memory interface circuit 117. In some embodiments, the non-volatile memory interface circuit 117 may be implemented based on the NAND interface.

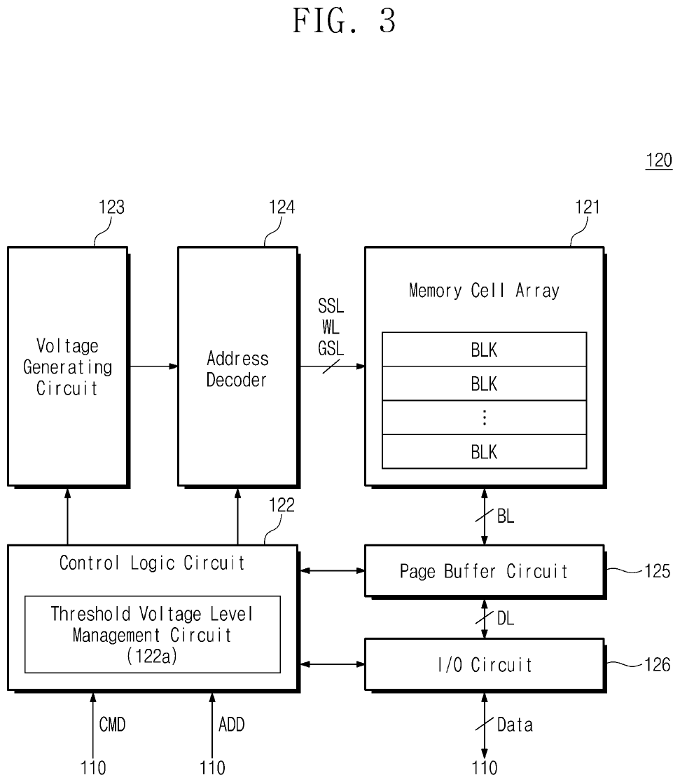

FIG. 3 is a block diagram describing the non-volatile memory device of FIG. 1, according to some embodiments of the present disclosure. Referring to FIGS. 1 and 3, the non-volatile memory device 120 may communicate with the storage controller 110. For example, the non-volatile memory device 120 may receive an address ADD and a command CMD from the storage controller 110. The non-volatile memory device 120 may perform data communication with the storage controller 110.

The non-volatile memory device 120 may include the memory cell array 121, the control logic circuit 122, a voltage generating circuit 123, an address decoder 124, a page buffer circuit 125, and an input/output (I/O) circuit 126.

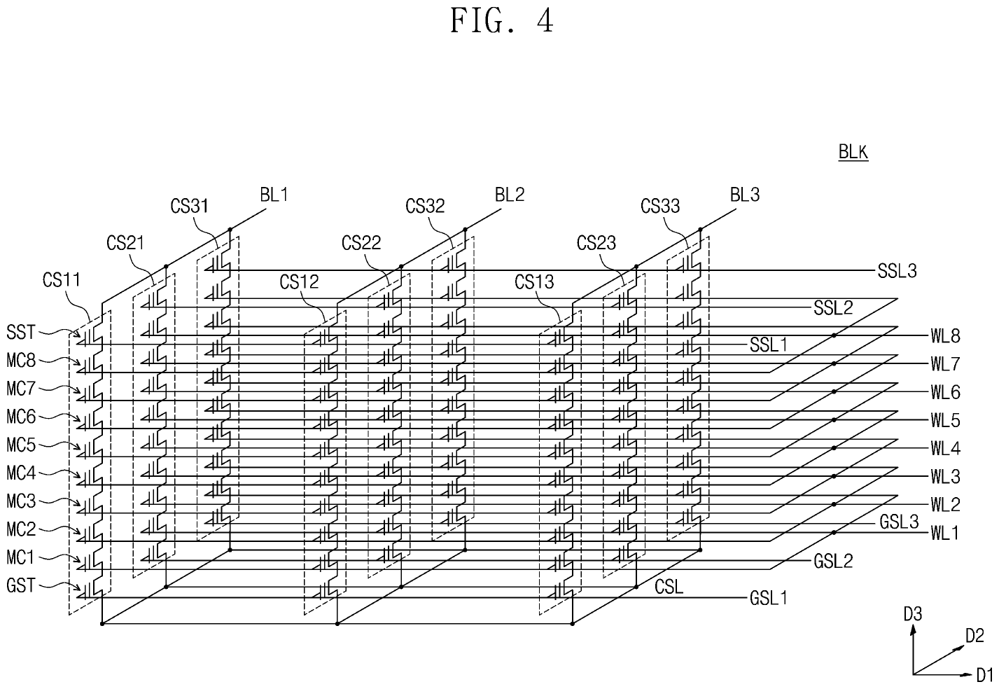

The memory cell array 121 may include the plurality of memory blocks BLK. Each of the plurality of memory blocks BLK may include the plurality of cell strings CS. Each of the cell strings CS may include a plurality of transistors. Some of the transistors may be used as a string selection transistor SST for identifying a corresponding cell string CS, and the others (or others) thereof may be used as memory cells for storing data. The memory block BLK will be described in detail with reference to FIG. 4.

The control logic circuit 122 may receive the command CMD and the address ADD from the storage controller 110. The command CMD may refer to a signal indicating a memory operation to be performed by the non-volatile memory device 120, such as a read operation or a write operation. The address ADD may be used to identify a location of memory cells where the memory operation is to be performed. The control logic circuit 122 may control all the operations of the non-volatile memory device 120 based on the command CMD and the address ADD.

The control logic circuit 122 may include the threshold voltage level management circuit 122a. The threshold voltage level management circuit 122a may store the voltage level information. The voltage level information may be used to determine the threshold voltage level of the string selection transistor SST. The voltage level information stored in the threshold voltage level management circuit 122a may be updated by the storage controller 110.

Under control of the control logic circuit 122, the voltage generating circuit 123 may provide voltages to the memory cell array 121 through the address decoder 124. For example, under control of the threshold voltage level management circuit 122a, the voltage generating circuit 123 may provide the programming voltage to the string selection transistor SST of the memory block BLK. The string selection transistor SST may have a threshold voltage level determined based on the programming voltage.

The address decoder 124 may receive the address ADD from the control logic circuit 122. The address decoder 124 may decode the address ADD. The address decoder 124 may be connected to the memory cell array 121 through string selection lines SSL, word lines WL, and ground selection lines GSL. The address decoder 124 may provide corresponding voltages to the string selection lines SSL, the word lines WL, and the ground selection lines GSL based on decoding information obtained by decoding the address ADD and the voltages received from the voltage generating circuit 123.

The page buffer circuit 125 may be connected to the memory cell array 121 through bit lines BL. The page buffer 125 may read data from the memory cell array 121 by sensing voltages of the bit lines BL under control of the control logic circuit 122. The page buffer circuit 125 may provide data to the I/O circuit 126 through data lines DL. The I/O circuit 126 may provide data to the storage controller 110.

The I/O circuit 126 may receive data from the storage controller 110. The I/O circuit 126 may provide the data to the page buffer circuit 125 through the data lines DL. The control logic circuit 122 may control the voltage generating circuit 123 and the address decoder 124 such that the data buffered by the page buffer circuit 125 are stored in the memory cell array 121.

FIG. 4 is a diagram describing a memory block of FIG. 3, according to some embodiments of the present disclosure. Referring to FIGS. 3 and 4, the memory cell array 121 may include the memory block BLK. The memory block BLK may refer to a unit by which the erase operation is performed in the non-volatile memory device 120, but the present invention is not limited thereto. The erase operation may be performed in units of page, word line, or sub-block smaller than the memory block BLK. According to some embodiments of the present disclosure, the memory block BLK may be implemented in a vertical-NAND (VNAND) type.

Below, for better understanding of the present disclosure, a first direction D1, a second direction D2, and a third direction D3 are mentioned. The first direction D1 may refer to a direction parallel to a semiconductor substrate (e.g., a substrate where the memory block BLK is formed). The second direction D2 may be perpendicular to the first direction D1. The third direction D3 may be perpendicular to a plane defined by the first direction D1 and the second direction D2. The third direction D3 may be perpendicular to the semiconductor substrate.

The memory block BLK may include a plurality of cell strings CS11, CS21, CS31, CS12, CS22, CS32, CS13, CS23, and CS33 arranged in the first direction D1 and the second direction D2. For better understanding of the present disclosure, 9 cell strings CS11, CS21, CS31, CS12, CS22, CS32, CS13, CS23, and CS33 will be described, but the present invention is not limited thereto. The number of cell strings included in the memory block BLK may increase or decrease in the first direction D1 or the second direction D2.

Each of the plurality of cell strings CS11, CS21, CS31, CS12, CS22, CS32, CS13, CS23, and CS33 may include a plurality of transistors connected in series. The plurality of transistors may be arranged along the third direction D3. The transistor may include a gate terminal. The transistor may be controlled based on a voltage applied to the gate terminal.

In some embodiments, the plurality of transistors may be implemented in a charge trap flash (CTF) type. The transistor of the CTF type may include a charge trap layer between the gate terminal and a p-type body. Electrons may be trapped in the charge trap layer, based on the programming voltage provided to the gate terminal. The threshold voltage level of the transistor may be determined based on the electrons trapped by the programming voltage. A determined threshold voltage level of a transistor functioning as a memory cell may correspond to data stored therein.

The cell strings CS11, CS21, and CS31 may be connected to a bit line BL1. The cell strings CS12, CS22, and CS32 may be connected to a bit line BL2. The cell strings CS13, CS23, and CS33 may be connected to a bit line BL3.

The transistors of the cell strings CS11, CS21, CS31, CS12, CS22, CS32, CS13, CS23, and CS33 may be controlled by string selection lines SSL1 to SSL3, word lines WL1 to WL8, and ground selection lines GSL1 to GSL3. For example, each of the cell strings CS11, CS21, CS31, CS12, CS22, CS32, CS13, CS23, and CS33 may include a ground selection transistor GST, memory cells MC1 to MC8, and the string selection transistor SST arranged along the third direction D3. Although not shown, in an embodiment, each of the cell strings CS11, CS21, CS31, CS12, CS22, CS32, CS13, CS23, and CS33 may include a plurality of ground selection transistors GST, more than or less than 8 of memory cells, and a plurality of string selection transistors SST arranged along the third direction D3.

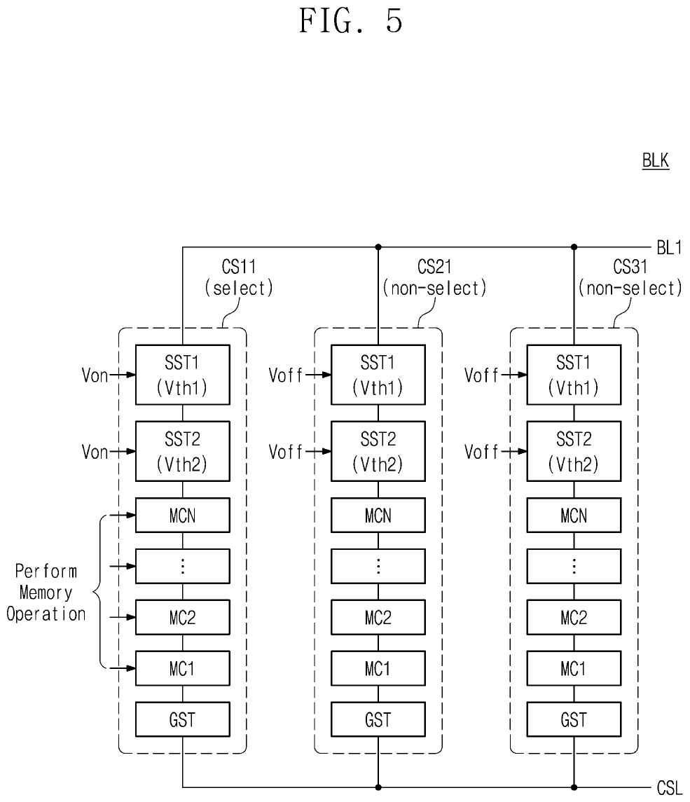

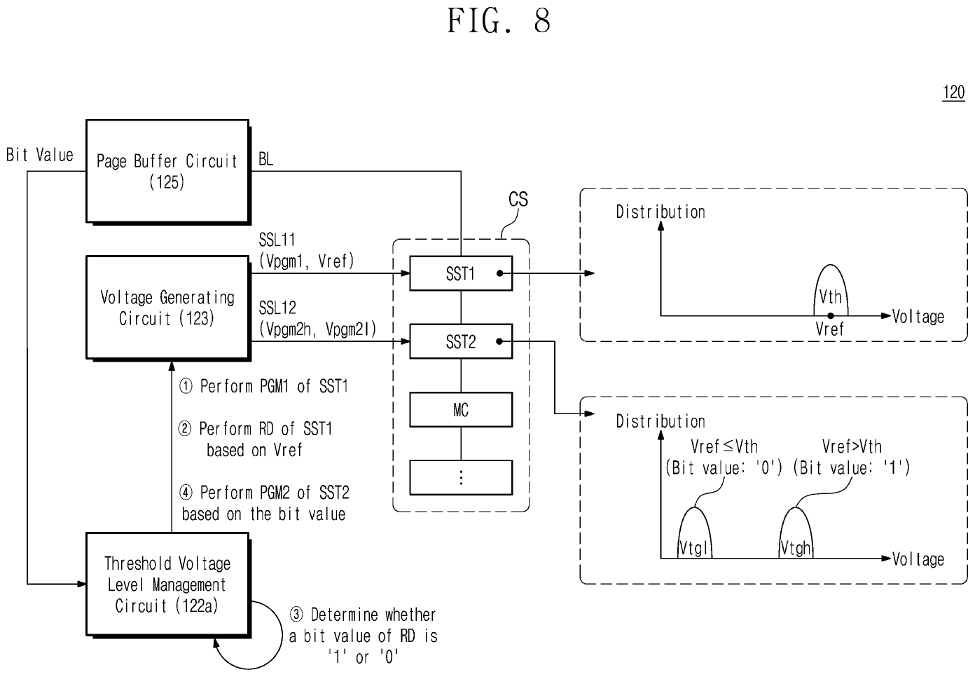

In detail, the ground selection transistor GST may be connected to the memory cell MC1 and a common source line CSL and may be controlled based on a voltage provided to the gate terminal through the ground selection line GSL1. The common source line CSL may be described as being adjacent to the semiconductor substrate in the third direction D3. The memory cells MC1 to MC8 may be respectively controlled by voltages provided to the gate terminals through the word lines WL1 to WL8. The string selection transistor SST may be connected to the first bit line BL1 and the memory cell MC8 and may be controlled based on a voltage provided to the gate terminal through the string selection line SSL1. For example, when the cell string has two string selection transistors SST1 and SST2 as shown in FIG. 5, the string selection transistors SST1 and SST2 may be connected in series between the first bit line BL1 and the memory cell MC8. In this case, the string selection transistors SST1 and SST2 may be connected to string selection lines SSL11 and SSL12 (shown in FIG. 8), respectively.

The description is given as the cell string CS11 includes one string selection transistor SST and 8 memory cells MC1 to MC8, but the present invention is not limited thereto. The cell string CS11 may include a plurality of selection transistors. The cell string CS11 may include memory cells, the number of which is more than or less than 8.

Likewise, as in the cell string CS11, each of the remaining cell strings CS21, CS31, CS12, CS22, CS32, CS13, CS23, and CS33 may include the ground selection transistor GST, the memory cells MC1 to MC8, and the string selection transistor SST arranged along the third direction D3.

Ground selection lines may be individually connected to cell strings sharing a bit line. For example, the ground selection line GSL1 may be connected to the gate terminals of the ground selection transistors GST of the cell strings CS11, CS12, and CS13. The ground selection line GSL2 may be connected to the gate terminals of the ground selection transistors GST of the cell strings CS21, CS22, and CS23. The ground selection line GSL3 may be connected to the gate terminals of the ground selection transistors GST of the cell strings CS31, CS32, and CS33.

A word line may be integrally connected to cell strings sharing a bit line. For example, the word line WL1 may be connected to the gate terminals of the memory cells MC1 of the cell strings CS11, CS21, CS31, CS12, CS22, CS32, CS13, CS23, and CS33. As in the above description, the word lines WL2 to WL8 may be connected to the gate terminals of the memory cells MC2 to MC8 of the cell strings CS11, CS21, CS31, CS12, CS22, CS32, CS13, CS23, and CS33.

String selection lines may be individually connected to cell strings sharing a bit line. For example, the string selection line SSL1 may be connected to the gate terminals of the string selection transistors SST of the cell strings CS11, CS12, and CS13. The string selection line SSL2 may be connected to the gate terminals of the string selection transistors SST of the cell strings CS21, CS22, and CS23. The string selection line SSL3 may be connected to the gate terminals of the string selection transistors SST of the cell strings CS31, CS32, and CS33.

FIG. 5 is a diagram describing a memory block to some embodiments of the present disclosure. Referring to FIG. 5, the memory block BLK may include the cell strings CS11, CS21, and CS31. The cell strings CS11, CS21, and CS31 may be connected in parallel between the first bit line BL1 and the common source line CSL.

Each of the cell strings CS11, CS21, and CS31 may include the ground selection transistor GST, first to N-th memory cells MC1 to MCN, a first string selection transistor SST1, and a second string selection transistor SST2. The first string selection transistor SST1 may be programmed to have a first threshold voltage level Vth1. The second string selection transistor SST2 may be programmed to have a second threshold voltage level Vth2. In an embodiment, “N” may indicate the number of memory cells included in a cell string. In an embodiment, “N” is an arbitrary natural number.

The first and second string selection transistors SST1 and SST2 may be programmed independently of each other. For example, the first threshold voltage level Vth1 of the first string selection transistor SST1 may be determined by applying a first programming voltage to the gate terminal of the first string selection transistor SST1. The second threshold voltage level Vth2 of the second string selection transistor SST2 may be determined by applying a second programming voltage to the gate terminal of the second string selection transistor SST2. The first threshold voltage level Vth1 may be higher than the second threshold voltage level Vth2. For example, in a cell string, as a distance from the semiconductor substrate increases, a threshold voltage level of a string selection transistor may be determined to be higher.

However, the present invention is not limited thereto. For example, the second threshold voltage level Vth2 may be determined to be higher than the first threshold voltage level Vth1. In this case, the first threshold voltage level Vth1 of the first string selection transistor SST1 adjacent to the first bit line BL1 may be lower than the second threshold voltage level Vth2 of the second string selection transistor SST2 adjacent to the N-th memory cell MCN. For example, in a cell string, as a distance from the semiconductor substrate increases, a threshold voltage level of a string selection transistor may be determined to be lower.

In one cell string, as the threshold voltage levels of the string selection transistors SST1 and SST2 are differently set, the negative effect by the drain induced barrier lowering (DIBL) may be suppressed. Also, as the threshold voltage levels of the string selection transistors SST1 and SST2 are differently set, the change in an energy band according to a distance between the first bit line BL1 and the N-th memory cell MCN may be slow.

After the first and second string selection transistors SST1 and SST2 of the cell strings CS11, CS21, and CS31 are completely programmed, in the memory block BLK, there may be performed the memory operation on one cell string. For example, the memory operation may include the read operation or the write operation. Because the erase operation on the entire memory block BLK is performed without distinguishing between the cell strings CS11, CS21, and CS31 (e.g., with the string selection transistors floated), the memory operation of a cell string may be referred to as a “read operation” or a “write operation”.

In the case of performing the memory operation on the cell string CS11 of the memory block BLK, the cell string CS11 may be selected, and the cell strings CS21 and CS31 may not be selected. A turn-on voltage Von may be provided to the gate terminals of the first and second string selection transistors SST1 and SST2 of the selected cell string CS11. Unlike the case of setting the first and second threshold voltage levels Vth1 and Vth2, the first and second string selection transistors SST1 and SST2 may be integrally used to select the cell string CS11. Current channels of the first and second string selection transistors SST1 and SST2 may be activated (or formed) based on the turn-on voltage Von. The first bit line BL1 and the N-th memory cell MCN may be electrically connected by the activated current channels.

As in the above description, a turn-off voltage Voff may be provided to the gate terminals of the first and second string selection transistors SST1 and SST2 of the unselected cell strings CS21 and CS31. The first and second string selection transistors SST1 and SST2 of the unselected cell strings CS21 and CS31 may be integrally used for the non-selection of the cell strings CS21 and CS31. Current channels of the first and second string selection transistors SST1 and SST2 of the unselected cell strings CS21 and CS31 may be blocked based on the turn-off voltage Voff. In this case, the first bit line BL1 and the N-th memory cell MCN of each of the of the unselected cell strings CS21 and CS31 may be electrically disconnected by the blocked current channels.

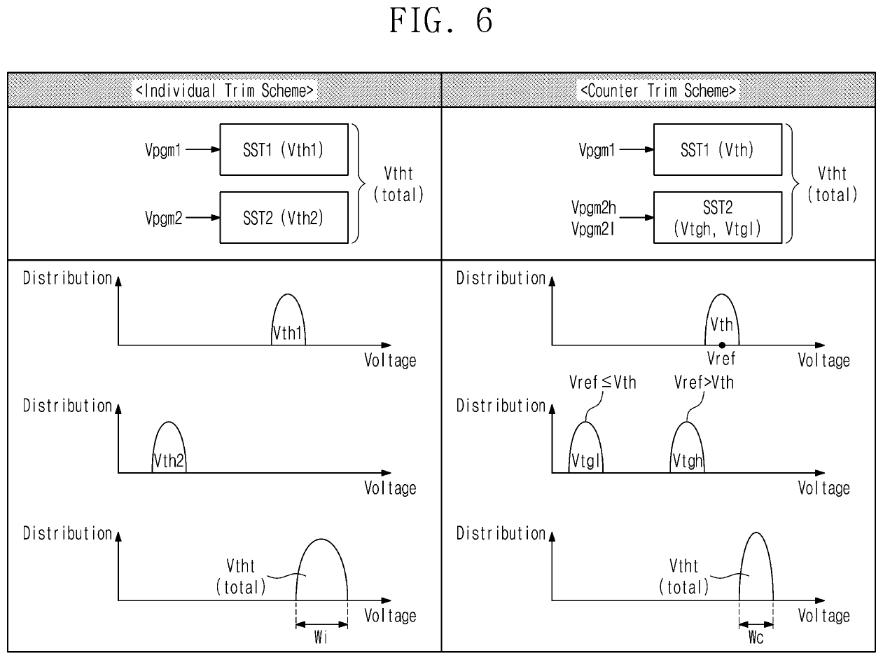

FIG. 6 is a diagram describing trim schemes according to some embodiments of the present disclosure. An “individual trim scheme” and a “counter trim scheme” for managing the threshold voltage levels of the first and second string selection transistors SST1 and SST2 belonging to the same cell string will be described with reference to FIG. 6. The first and second string selection transistors SST1 and SST2 may be connected in series between a corresponding bit line and a corresponding memory cell.

Referring to the individual trim scheme, a first programming voltage Vpgm1 may be provided to the gate terminal of the first string selection transistor SST1. Electrons may be trapped in the charge trap layer of the first string selection transistor SST1, based on the first programming voltage Vpgm1. The threshold voltage level of the first string selection transistor SST1 may be determined to the first threshold voltage level Vth1, based on the trapped electrons corresponding to the first programming voltage Vpgm1.

Referring to a graph of the first threshold voltage level Vth1, a horizontal axis represents a voltage, and a vertical axis represents a distribution. The distribution may indicate the number of transistors having the corresponding voltage level under similar (or substantially the same) conditions or may indicate the probability of having the corresponding voltage level. The threshold voltage level of the first string selection transistor SST1 may be determined to a voltage in the distribution of the first threshold voltage level Vth1, due to various factors such as a physical limit, an element characteristic, and the fluctuations in the first programming voltage Vpgm1.

A second programming voltage Vpgm2 may be provided to the gate terminal of the second string selection transistor SST2. The threshold voltage level of the second string selection transistor SST2 may be determined to the second threshold voltage level Vth2, based on the trapped electrons corresponding to the second programming voltage Vpgm2. Referring to a graph of the second threshold voltage level Vth2, the horizontal axis represents a voltage, and the vertical axis represents a distribution. The second threshold voltage level Vth2 may be lower than the first threshold voltage level Vth1.

Afterwards, in the memory operation on the cell string including the first and second string selection transistors SST1 and SST2, the first and second string selection transistors SST1 and SST2 may be integrally used. The first and second string selection transistors SST1 and SST2 may integrally have a total threshold voltage level Vtht. Referring to a graph of the total threshold voltage level Vtht, the horizontal axis represents a voltage, and the vertical axis represents a distribution. The total threshold voltage level Vtht may have a width Wi.

In this case, the turn-on voltage may be determined to be higher than the highest voltage (or the upper limit) of the distribution corresponding to the total threshold voltage level Vtht, and the turn-off voltage may be determined to be lower than the lowest voltage (or the lower limit) of the distribution corresponding to the total threshold voltage level Vtht. When the width Wi of the total threshold voltage level Vtht becomes narrower, the cell string including the first and second string selection transistors SST1 and SST2 may be accurately selected, and a voltage margin for the cell string operation of the non-volatile memory device may be improved. This may mean that all the driving voltages of the non-volatile memory device decrease. The counter trim scheme may be considered to decrease the width Wi of the total threshold voltage level Vtht.

Referring to the counter trim scheme, the first programming voltage Vpgm1 may be provided to the gate terminal of the first string selection transistor SST1. The threshold voltage level Vth of the first string selection transistor SST1 may be determined based on the trapped electrons corresponding to the first programming voltage Vpgm1. Referring to the graph of the threshold voltage level Vth, the horizontal axis represents a voltage, and the vertical axis represents a distribution.

A reference voltage Vref may be included in a voltage range of the distribution corresponding to the threshold voltage level Vth. For example, the reference voltage Vref may correspond to the middle of the distribution corresponding to the threshold voltage level Vth (however, the present invention is not limited thereto). The reference voltage Vref may be used to determine whether the programmed threshold voltage level Vth of the first string selection transistor SST1 corresponds to a high voltage or a low voltage in the distribution.

For example, after the first string selection transistor SST1 is programmed based on the first programming voltage Vpgm1, the reference voltage Vref may be provided to the gate terminal of the first string selection transistor SST1. The reference voltage Vref may be considerably lower than the first programming voltage Vpgm1 (e.g., may be low enough to have no influence on the trap of electrons). To provide the reference voltage Vref may be substantially similar to that in the read operation.

When the reference voltage Vref exceeds the threshold voltage level Vth (herein, not the distribution but an actually programmed specific voltage level), the current channel of the first string selection transistor SST1 may be activated. A first electrical signal (e.g., a turn-on current) corresponding to a first logical value (e.g., “1”) may be provided to a bit line, based on the activated current channel.

In response to that the first electrical signal is generated, a second high programming voltage Vpgm2h may be provided to the gate terminal of the second string selection transistor SST2. The threshold voltage level of the second string selection transistor SST2 may be determined to a high target threshold voltage level Vtgh, based on the trapped electrons corresponding to the second high programming voltage Vpgm2h. The high target threshold voltage level Vtgh may be lower than the threshold voltage level Vth of the first string selection transistor SST1. A level of the second high programming voltage Vpgm2h may be lower than a level of the first programming voltage Vpgm1.

As in the above description, when the reference voltage Vref does not exceed (or, is lower than) the threshold voltage level Vth (herein, not the distribution but an actually programmed specific voltage level), the current channel of the first string selection transistor SST1 may be blocked. A second electrical signal (e.g., a turn-off current) corresponding to a second logical value (e.g., “0”) opposite to the first logical value may be provided to a bit line, based on the blocked current channel.

In response to that the second electrical signal is generated, a second low programming voltage Vpgm2l may be provided to the gate terminal of the second string selection transistor SST2. The threshold voltage level of the second string selection transistor SST2 may be determined to a low target threshold voltage level Vtgl, based on the trapped electrons corresponding to the second low programming voltage Vpgm2l. A level of the second low programming voltage Vpgm2l may be lower than the level of the second high programming voltage Vpgm2h.

Referring to a graph of the high target threshold voltage level Vtgh and the low target threshold voltage level Vtgl, the horizontal axis represents a voltage, and the vertical axis represents a distribution. The case where the reference voltage Vref exceeds the threshold voltage level Vth may mean that the first string selection transistor SST1 is programmed to a low voltage in the distribution corresponding to the threshold voltage level Vth. In this case, the second string selection transistor SST2 may be programmed to the high target threshold voltage level Vtgh.

As in the above description, the case where the reference voltage Vref does not exceed (or, is lower than) the threshold voltage level Vth may mean that the first string selection transistor SST1 is programmed to a high voltage in the distribution corresponding to the threshold voltage level Vth. In this case, the second string selection transistor SST2 may be programmed to the low target threshold voltage level Vtgl.

Afterwards, in the memory operation on the cell string including the first and second string selection transistors SST1 and SST2, the first and second string selection transistors SST1 and SST2 may be integrally used. The first and second string selection transistors SST1 and SST2 may integrally have the total threshold voltage level Vtht. Referring to the graph of the total threshold voltage level Vtht, the horizontal axis represents a voltage, and the vertical axis represents a distribution. The total threshold voltage level Vtht may have a width Wc. The width Wc of the total threshold voltage level Vtht corresponding to the counter trim scheme may be narrower than the width Wi of the total threshold voltage level Vtht corresponding to the individual trim scheme.

For example, as the counter trim scheme is applied, depending on whether the actually programmed threshold voltage level Vth of the first string selection transistor SST1 is high or low in the distribution, the second high programming voltage Vpgm2h and the second low programming voltage Vpgm2l may be selectively applied to the second string selection transistor SST2 adjacent to the first string selection transistor SST1, and thus, the width of the total threshold voltage level Vtht of the first and second string selection transistors SST1 and SST2 may decrease. According to the above description, the cell string may be accurately selected, and a driving voltage of the non-volatile memory device may decrease.

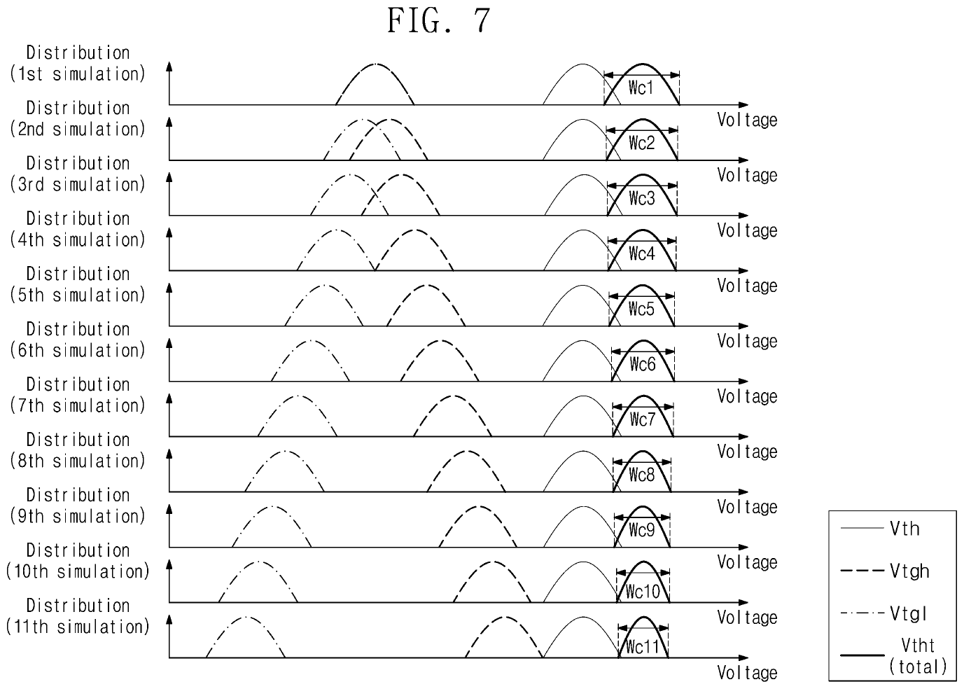

FIG. 7 is a diagram describing simulations of a counter trim scheme according to some embodiments of the present disclosure. Referring to FIG. 7, a cell string may include the first and second string selection transistors SST1 and SST2. The counter trim scheme may be applied to the first and second string selection transistors SST1 and SST2. As it goes from the first simulation toward the eleventh simulation, a difference between the high target threshold voltage level Vtgh and the low target threshold voltage level Vtgl may increase. In each graph, the horizontal axis represents a voltage, and the vertical axis represents a distribution.

The first string selection transistor SST1 may have the threshold voltage level Vth. The waveform of the threshold voltage level Vth is illustrated by a solid line. Depending on whether the actually programmed threshold voltage level Vth is high or low, the second string selection transistor SST2 may be programmed to have the high target threshold voltage level Vtgh or the low target threshold voltage level Vtgl. The high target threshold voltage level Vtgh is illustrated by a dashed line. The low target threshold voltage level Vtgl is illustrated by a dash-dotted line. The total threshold voltage level Vtht of the first and second string selection transistors SST1 and SST2 is illustrated by a thick solid line.

Referring to the first simulation, there may be almost no difference between the high target threshold voltage level Vtgh and the low target threshold voltage level Vtgl. The total threshold voltage level Vtht may have a width Wc1.

As in the above description, referring to the second to eleventh simulations, a difference between the high target threshold voltage level Vtgh and the low target threshold voltage level Vtgl may sequentially (or gradually) increase. Each of widths Wc2 to Wc11 may be respectively measured in the second to eleventh simulations.

For example, according to the first to eleventh simulations, as the difference between the high target threshold voltage level Vtgh and the low target threshold voltage level Vtgl increases, the width of the total threshold voltage level Vtht of the first and second string selection transistors SST1 and SST2 may decrease.

FIG. 8 is a diagram describing a method of operating a non-volatile memory device according to some embodiments of the present disclosure. Referring to FIG. 8, the non-volatile memory device 120 may include the memory cell array 121, the threshold voltage level management circuit 122a, the voltage generating circuit 123, and the page buffer circuit 125.

The memory cell array 121 may include the memory block BLK. The memory block BLK may include the cell string CS. The cell string CS may include the first string selection transistor SST1, the second string selection transistor SST2, and the memory cells MC. The first and second string selection transistors SST1 and SST2 may be respectively connected to first and second string selection lines SSL11 and SSL12. The cell string CS may be connected to the page buffer circuit 125 through the bit line BL.

Below, a method of operating the non-volatile memory device 120 will be described in detail.

In a first operation \textcircled{1}, the threshold voltage level management circuit 122a may perform a first programming operation PGM1 of the first string selection transistor SST1 through the voltage generating circuit 123. For example, under control of the threshold voltage level management circuit 122a, the voltage generating circuit 123 may provide the first programming voltage Vpgm1 to the gate terminal of the first string selection transistor SST1 through the first string selection line SSL11. Electrons may be trapped in the charge trap layer of the first string selection transistor SST1 based on the first programming voltage Vpgm1. The threshold voltage level management circuit 122a may determine the threshold voltage level Vth of the first string selection transistor SST1, based on the trapped electrons corresponding to the first programming voltage Vpgm1. For example, the first string selection transistor SST1 may have the threshold voltage level Vth determined based on the trapped electrons.

Referring to the graph of the first string selection transistor SST1, the horizontal axis represents a voltage, and the vertical axis represents a distribution. The first string selection transistor SST1 may have, as a threshold voltage level, an arbitrary voltage belonging to the waveform of the threshold voltage level Vth illustrated in the graph. The reference voltage Vref may exceed the actually programmed threshold voltage level Vth of the first string selection transistor SST1 or may not exceed (or lower than) the actually programmed threshold voltage level Vth of the first string selection transistor SST1.

In a second operation \textcircled{2}, the threshold voltage level management circuit 122a may perform a read operation RD of the first string selection transistor SST1 through the voltage generating circuit 123, based on the reference voltage Vref. For example, under control of the threshold voltage level management circuit 122a, the voltage generating circuit 123 may provide the reference voltage Vref to the gate terminal of the first string selection transistor SST1 through the first string selection line SSL11.

For example, when the reference voltage Vref exceeds the actually programmed threshold voltage level Vth of the first string selection transistor SST1, the current channel of the first string selection transistor SST1 may be activated (or formed) based on the reference voltage Vref. The first string selection transistor SST1 may provide the first electrical signal (e.g., a turn-on current) corresponding to a bit value indicating the first logical value (e.g., “1”) to the page buffer circuit 125 through the bit line BL, based on the activated current channel.

As another example, when the reference voltage Vref does not exceed (or, is lower than) the actually programmed threshold voltage level Vth of the first string selection transistor SST1, the current channel of the first string selection transistor SST1 may be blocked based on the reference voltage Vref. The first string selection transistor SST1 may provide the second electrical signal (e.g., a turn-off current) corresponding to a bit value indicating the second logical value (e.g., “0”) to the page buffer circuit 125 through the bit line BL, based on the blocked current channel.

The threshold voltage level management circuit 122a may receive the bit value of the read operation RD from the page buffer circuit 125. However, the present invention is not limited thereto. For example, the threshold voltage level management circuit 122a may receive the bit value of the read operation RD from the page buffer circuit 125 through the I/O circuit 126 of FIG. 3 or a separate transmission circuit (not illustrated).

In a third operation \textcircled{3}, the threshold voltage level management circuit 122a may determine whether the bit value of the read operation RD indicates the first logical value (e.g., “1”) or the second logical value (e.g., “0”). The case where the bit value indicates the first logical value (e.g., “1”) may mean that the threshold voltage level Vth of the first string selection transistor SST1 is determined to be low in the distribution range. In this case, it may be appropriate to determine the threshold voltage level of the second string selection transistor SST2 to be high.

In contrast, the case where the bit value indicates the second logical value (e.g., “0”) may mean that the threshold voltage level Vth of the first string selection transistor SST1 is determined to be high in the distribution range. In this case, it may be appropriate to determine the threshold voltage level of the second string selection transistor SST2 to be low.

Referring to a fourth operation \textcircled{4}, the threshold voltage level management circuit 122a may perform a second programming operation PGM2 of the second string selection transistor SST2 through the voltage generating circuit 123 based on the bit value of the first string selection transistor SST1.

For example, in response to that the bit value indicates the first logical value (e.g., “1”), the threshold voltage level management circuit 122a may control the voltage generating circuit 123 such that the second high programming voltage Vpgm2h is generated. Under control of the threshold voltage level management circuit 122a, the voltage generating circuit 123 may provide the second high programming voltage Vpgm2h to the gate terminal of the second string selection transistor SST2 through the second string selection line SSL12. The threshold voltage level management circuit 122a may determine the threshold voltage level of the second string selection transistor SST2 to the high target threshold voltage level Vtgh, based on the trapped electrons corresponding to the second high programming voltage Vpgm2h. The high target threshold voltage level Vtgh may be lower than the threshold voltage level Vth of the first string selection transistor SST1.

As another example, in response to that the bit value indicates the second logical value (e.g., “0”), the threshold voltage level management circuit 122a may control the voltage generating circuit 123 such that the second low programming voltage Vpgm2l is generated. Under control of the threshold voltage level management circuit 122a, the voltage generating circuit 123 may provide the second low programming voltage Vpgm2l to the gate terminal of the second string selection transistor SST2 through the second string selection line SSL12. The threshold voltage level management circuit 122a may determine the threshold voltage level of the second string selection transistor SST2 to the low target threshold voltage level Vtgl, based on the trapped electrons corresponding to the second low programming voltage Vpgm2l.

Referring to the graph of the second string selection transistor SST2, the horizontal axis represents a voltage, and the vertical axis represents a distribution. When the bit value of the first string selection transistor SST1 indicates the first logical value (e.g., “1”), the second string selection transistor SST2 may have, as a threshold voltage level, an arbitrary voltage belonging to the waveform of the illustrated high target threshold voltage level Vtgh. When the bit value of the first string selection transistor SST1 indicates the second logical value (e.g., “0”), the second string selection transistor SST2 may have, as a threshold voltage level, an arbitrary voltage belonging to the waveform of the illustrated low target threshold voltage level Vtgl.

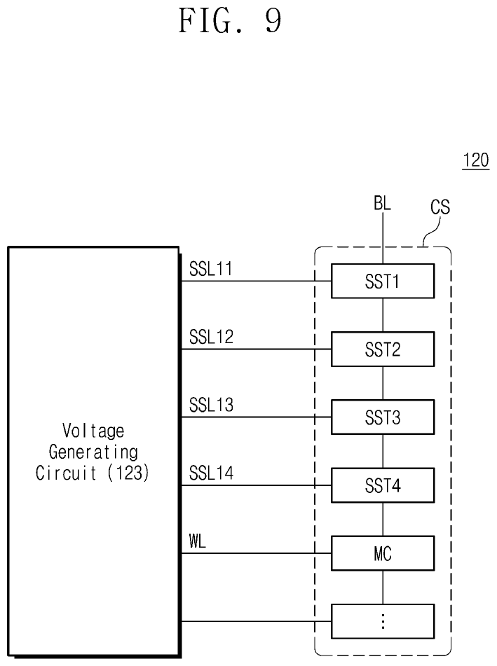

FIG. 9 is a diagram describing a non-volatile memory device according to some embodiments of the present disclosure. Referring to FIG. 9, the non-volatile memory device 120 may include the memory cell array 121 and the voltage generating circuit 123. The memory cell array 121 may include the memory block BLK. The memory block BLK may include the cell string CS. The cell string CS may be connected to the bit line BL.

The cell string CS may include first to fourth string selection transistors SST1 to SST4 and the memory cell MC. The first to fourth string selection transistors SST11, SST12, SST13, and SST14 may be connected in series between the bit line BL and the memory cell MC. The voltage generating circuit 123 may provide voltages to the gate terminals of the first to fourth string selection transistors SST1 to SST4 through first to fourth string selection lines SSL11, SSL12, SSL13, and SSL14. The voltage generating circuit 123 may provide a voltage to the gate terminal of the memory cell MC through the word line WL. In this case, in detail, the cell string CS may include the first to fourth string selection transistors SST1 to SST4, one or more memory cells MC, and one or more ground selection transistors GST connected in series between the bit line BL and the common source line CSL.

According to some embodiments of the present disclosure, the cell string CS may include two or more string selection transistors. For example, as the V-NAND-type memory block BLK is highly integrated, the number of transistors connected in series in the cell string CS may increase (e.g., to several hundreds). Even though a transistor of the cell string CS is used as a string selection transistor instead of the memory cell MC, the burden on the string selection transistor may decrease.

For better understanding of the present disclosure, four string selection transistors SST1 to SST4 are illustrated, but the cell string CS may include three string selection transistors or may include 4 or more string selection transistors.

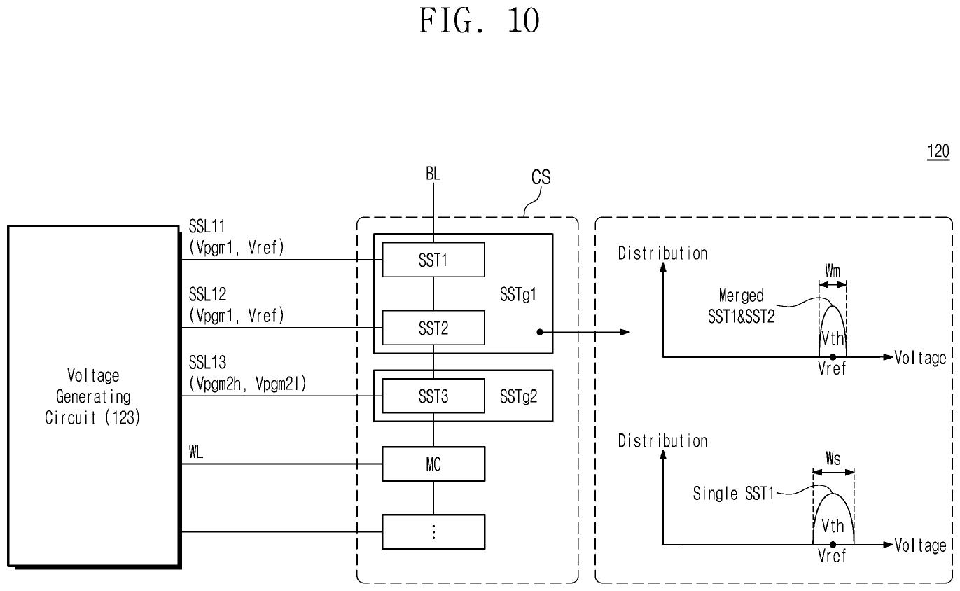

As three or more string selection transistors are used, the non-volatile memory device 120 may support a merged counter trim operation. This will be described in detail with reference to FIG. 10.

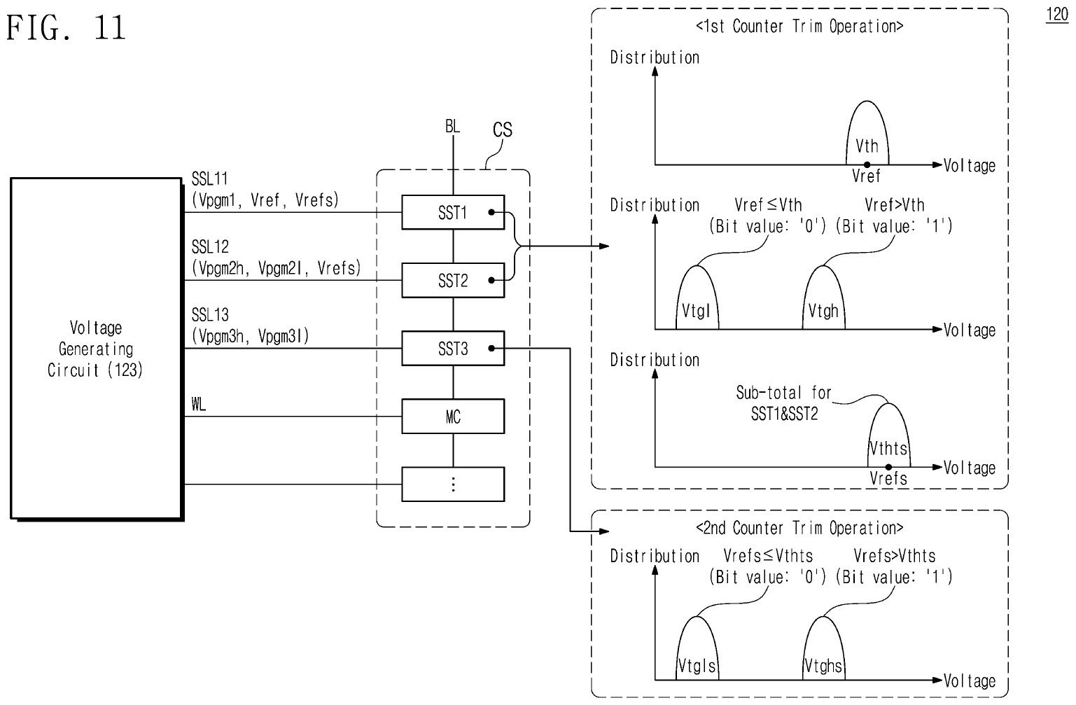

Also, as three or more string selection transistors are used, the non-volatile memory device 120 may support a continuous counter trim operation. This will be described in detail with reference to FIG. 11.

In some embodiments, the voltage generating circuit 123 may determine a threshold voltage level of a string selection transistor adjacent to the bit line BL to be high. For example, the first string selection transistor SST1 may be connected between the bit line BL and the second string selection transistor SST2. The voltage generating circuit 123 may provide a high programming voltage (e.g., Vpgm1 of FIG. 8) to the gate terminal of the first string selection transistor SST1 through the first string selection line SSL11. Afterwards, the voltage generating circuit 123 may provide a low programming voltage (e.g., Vpgm2h or Vpgm2l of FIG. 8) to the gate terminal of the second string selection transistor SST2 through the second string selection line SSL12.

In some embodiments, the voltage generating circuit 123 may determine a threshold voltage level of a string selection transistor adjacent to the bit line BL to be low. For example, the first string selection transistor SST1 may be connected between the bit line BL and the second string selection transistor SST2. The voltage generating circuit 123 may provide a high programming voltage (e.g., Vpgm1 of FIG. 8) to the gate terminal of the second string selection transistor SST2 through the second string selection line SSL12. Afterwards, the voltage generating circuit 123 may provide a low programming voltage (e.g., Vpgm2h or Vpgm2l of FIG. 8) to the gate terminal of the first string selection transistor SST1 through the first string selection line SSL11.

FIG. 10 is a diagram describing a merged counter trim operation according to some embodiments of the present disclosure. Referring to FIG. 10, the non-volatile memory device 120 may include the memory cell array 121 and the voltage generating circuit 123. The memory cell array 121 may include the memory block BLK. The memory block BLK may include the cell string CS. The cell string CS may be connected to the bit line BL.

The cell string CS may include first to third string selection transistors SST1 to SST3 and the memory cell MC. The first to third string selection transistors SST1 to SST3 may be connected in series between the bit line BL and the memory cell MC. The voltage generating circuit 123 may provide voltages to the gate terminals of the first to third string selection transistors SST1 to SST3 through first to third string selection lines SSL11, SSL12 and SSL13. The voltage generating circuit 123 may provide a voltage to the gate terminal of the memory cell MC through the word line WL. In this case, in detail, the cell string CS may include the first to third string selection transistors SST1 to SST3, one or more memory cells MC, and one or more ground selection transistors GST connected in series between the bit line BL and the common source line CSL.

The non-volatile memory device 120 may support the merged counter trim operation. The merged counter trim operation may refer to an operation of replacing at least one of two string selection transistors, to which the counter trim operation is applied, with a plurality of transistors merged.

For example, the first and second string selection transistors SST1 and SST2 may be merged into a first group SSTg1. The first group SSTg1 may be collectively referred to as the “first and second string selection transistors SST1 and SST2”. The third string selection transistor SST3 may be used as a second group SSTg2. The second group SSTg2 may refer to the third string selection transistor SST3.

The voltage generating circuit 123 may provide the first programming voltage Vpgm1 to the first group SSTg1 through the first and second string selection lines SSL11 and SSL12. the first group SSTg1 may have the threshold voltage level Vth based on injected electrons corresponding to the first programming voltage Vpgm1. In this case, the first programming voltage Vpgm1 may be provided to all the gate terminals of the first and second string selection transistors SST1 and SST2. The first and second string selection transistors SST1 and SST2 may operate like one large transistor.

Referring to a graph of the merged counter trim operation, a distribution of the threshold voltage level Vth of the merged first and second string selection transistors SST1 and SST2 of the first group SSTg1 may have a width Wm. As a comparative example, a distribution of the threshold voltage level Vth of a single first string selection transistor SST1 may have a width Ws.

The width Wm corresponding to the merged string selection transistors may be narrower than the width Ws of the distribution corresponding to the single string selection transistor. For example, as two or more string selection transistors are merged, the width of the distribution corresponding to the threshold voltage level Vth may decrease.

After the programming operation on the first group SSTg1 is completed, the voltage generating circuit 123 may provide the reference voltage Vref to the first group SSTg1 through the first and second string selection lines SSL11 and SSL12. In this case, the reference voltage Vref may be provided to all the gate terminals of the first and second string selection transistors SST1 and SST2. Depending on a bit value obtained by the read operation performed based on the reference voltage Vref, the voltage generating circuit 123 may provide the second high programming voltage Vpgm2h or the second low programming voltage Vpgm2l to the second group SSTg2 through the third string selection line SSL13.

For better understanding of the present disclosure, the description is given as the first group SSTg1 includes two string selection transistors SST1 and SST2 merged, but the present invention is not limited thereto. The first group SSTg1 may include three or more string selection transistors, or the second group SSTg2 may further include at least another string selection transistor merged with the third string selection transistor SST3.

FIG. 11 is a diagram describing continuous counter trim operations according to some embodiments of the present disclosure. Referring to FIG. 11, the non-volatile memory device 120 may include the memory cell array 121 and the voltage generating circuit 123. The memory cell array 121 may include the memory block BLK. The memory block BLK may include the cell string CS. The cell string CS may be connected to the bit line BL.

The cell string CS may include the first to third string selection transistors SST1 to SST3 and the memory cell MC. The first to third string selection transistors SST1 to SST3 may be connected in series between the bit line BL and the memory cell MC. The voltage generating circuit 123 may provide voltages to the gate terminals of the first to third string selection transistors SST1 to SST3 through the first to third string selection lines SSL11 to SLL13. The voltage generating circuit 123 may provide a voltage to the gate terminal of the memory cell MC through the word line WL. In this case, in detail, the cell string CS may include the first to third string selection transistors SST1 to SST3, one or more memory cells MC, and one or more ground selection transistors GST connected in series between the bit line BL and the common source line CSL.

The non-volatile memory device 120 may support continuous counter trim operations. The continuous counter trim operations may mean the execution of two or more counter trim operations in the same cell string. For example, the continuous counter trim operations may include a first counter trim operation and a second counter trim operation.

In the first counter trim operation, the voltage generating circuit 123 may provide the first programming voltage Vpgm1 to the first string selection transistor SST1. The first string selection transistor SST1 may have the threshold voltage level Vth by providing the first programming voltage Vpgm1 to the first string selection transistor SST1.

The voltage generating circuit 123 may provide the reference voltage Vref to the first string selection transistor SST1. When the reference voltage Vref exceeds the threshold voltage level Vth, a bit value indicating the first logical value (e.g., “1”) may be obtained. When the reference voltage Vref does not exceed (or, is lower than) the threshold voltage level Vth, a bit value indicating the second logical value (e.g., “0”) may be obtained.

The voltage generating circuit 123 may provide the second high programming voltage Vpgm2h or the second low programming voltage Vpgm2l lower than second high programming voltage Vpgm2h to the second string selection transistor SST2 depending on the obtained bit value. The second string selection transistor SST2 may have the high target threshold voltage level Vtgh or the low target threshold voltage level Vtgl. The first and second string selection transistors SST1 and SST2 may collectively have a sub-total threshold voltage level Vthts.

Afterwards, the non-volatile memory device 120 may handle the first and second string selection transistors SST1 and SST2 as one string selection transistor and may perform the second counter trim operation for programming the third string selection transistor SST3.

In the second counter trim operation, the voltage generating circuit 123 may provide a sub-reference voltage Vrefs to the first and second string selection transistors SST1 and SST2. When the sub-reference voltage Vrefs exceeds the sub-total threshold voltage level Vthts, a bit value indicating the first logical value (e.g., “1”) may be obtained. When the sub-reference voltage Vrefs does not exceed (or, is lower than) the sub-total threshold voltage level Vthts, a bit value indicating the second logical value (e.g., “0”) may be obtained.

The voltage generating circuit 123 may provide a third high programming voltage Vpgm3h or a third low programming voltage Vpgm31 lower than the third high programming voltage Vpgm3h to the third string selection transistor SST3 depending on the obtained bit value of the sub-total threshold voltage level Vthts. The third string selection transistor SST3 may have a sub-high target threshold voltage level Vtghs or a sub-low target threshold voltage level Vtgl.

For better understanding of the present disclosure, two continuous counter trim operations are described, but the present invention is not limited thereto. In some embodiments, the non-volatile memory device 120 may perform the first and second counter trim operations, may then handle the first to third string selection transistors SST1 to SST3 as one string selection transistor, and may further perform a third counter trim operation for programming a fourth string selection transistor (not illustrated) added between the third string selection transistor SST3 and the memory cell MC. Also, the continuous counter trim operations may be applied in combination with the merged counter trim operation of FIG. 10.

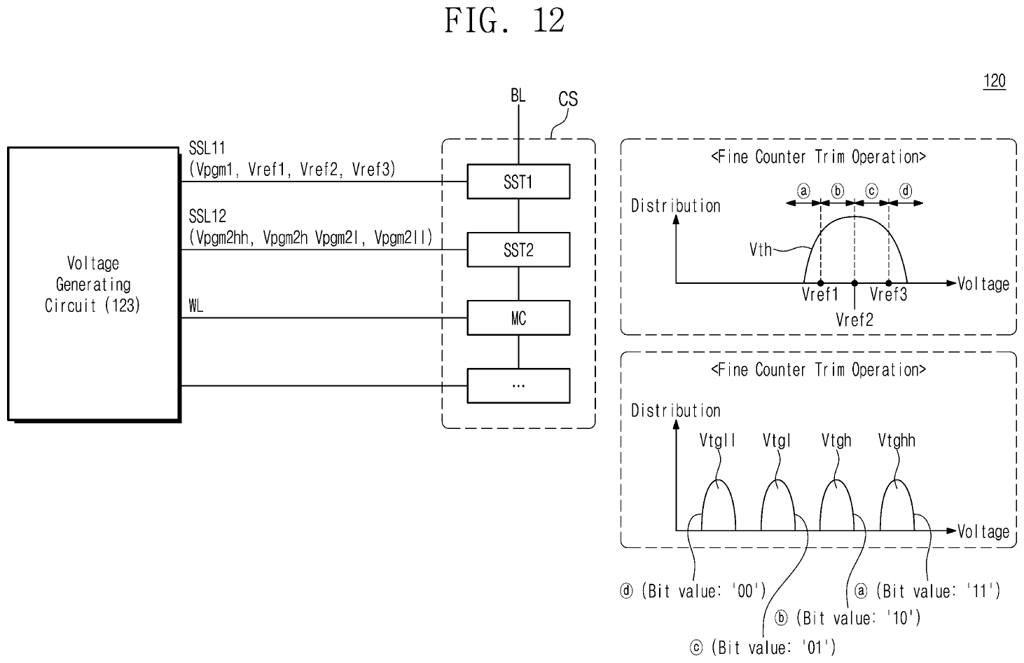

FIG. 12 is a diagram describing a fine counter trim operation according to some embodiments of the present disclosure. Referring to FIG. 12, the non-volatile memory device 120 may include the memory cell array 121 and the voltage generating circuit 123. The memory cell array 121 may include the memory block BLK. The memory block BLK may include the cell string CS. The cell string CS may be connected to the bit line BL.

The cell string CS may include first and second string selection transistors SST1 and SST2 and the memory cell MC. The first and second string selection transistors SST1 to SST2 may be connected in series between the bit line BL and the memory cell MC. The voltage generating circuit 123 may provide voltages to the gate terminals of the first and second string selection transistors SST1 and SST2 through the first and second string selection lines SSL11 and SSL12. The voltage generating circuit 123 may provide a voltage to the gate terminal of the memory cell MC through the word line WL. In this case, in detail, the cell string CS may include the first and second string selection transistors SST1 and SST2, one or more memory cells MC, and one or more ground selection transistors GST connected in series between the bit line BL and the common source line CSL.

The non-volatile memory device 120 may support a fine counter trim operation. The fine counter trim operation may mean that subsequent programming operations are performed with a threshold voltage level divided into two or more sections.

The voltage generating circuit 123 may provide the first programming voltage Vpgm1 to the first string selection transistor SST1. The first string selection transistor SST1 may have the threshold voltage level Vth. The threshold voltage level Vth may be divided into four voltage sections \textcircled{a}, \textcircled{b}, \textcircled{c}, and \textcircled{d} by first to third reference voltages Vref1 to Vref3.

The voltage generating circuit 123 may provide the first to third reference voltages Vref1 to Vref3 to the first string selection transistor SST1. A bit value may include two continuous bits, that is, a first bit and a second bit. The second reference voltage Vref2 may be used to determine the first bit. The first and third reference voltages Vref1 and Vref3 may be used to determine the second bit.

For example, when the first string selection transistor SST1 is turned on by the second reference voltage Vref2 and is turned on by the first reference voltage Vref1, a bit value indicating a logical value of “11” corresponding to the voltage section \textcircled{a} may be obtained.

For example, when the first string selection transistor SST1 is turned on by the second reference voltage Vref2 and is turned off by the first reference voltage Vref1, a bit value indicating a logical value of “10” corresponding to the voltage section \textcircled{b} may be obtained.

For example, when the first string selection transistor SST1 is turned off by the second reference voltage Vref2 and is turned on by the third reference voltage Vref3, a bit value indicating a logical value of “01” corresponding to the voltage section \textcircled{c} may be obtained.

For example, when the first string selection transistor SST1 is turned off by the second reference voltage Vref2 and is turned off by the third reference voltage Vref3, a bit value indicating a logical value of “00” corresponding to the voltage section \textcircled{d} may be obtained.

The voltage generating circuit 123 may program the second string selection transistor SST2 depending on the obtained bit value.

For example, in response to the bit value indicating the logical value of “11”, the voltage generating circuit 123 may provide a second highest programming voltage Vpgm2hh to the gate terminal of the second string selection transistor SST2. In this case, the threshold voltage level of the second string selection transistor SST2 may be programmed to a highest target threshold voltage level Vtghh.

For example, in response to the bit value indicating the logical value of “10”, the voltage generating circuit 123 may provide the second high programming voltage Vpgm2h to the gate terminal of the second string selection transistor SST2. In this case, the threshold voltage level of the second string selection transistor SST2 may be programmed to the high target threshold voltage level Vtgh.

For example, in response to the bit value indicating the logical value of “01”, the voltage generating circuit 123 may provide the second low programming voltage Vpgm2l to the gate terminal of the second string selection transistor SST2. In this case, the threshold voltage level of the second string selection transistor SST2 may be programmed to the low target threshold voltage level Vtgl.

For example, in response to the bit value indicating the logical value of “00”, the voltage generating circuit 123 may provide a second lowest programming voltage Vpgm2ll to the gate terminal of the second string selection transistor SST2. In this case, the threshold voltage level of the second string selection transistor SST2 may be programmed to a lowest target threshold voltage level Vtgll.

For better understanding of the present disclosure, the description is given as the fine counter trim operation includes four voltage sections, but the present invention is not limited thereto. The fine counter trim operation may include voltage sections, the number of which is more than or less than four. Also, the fine counter trim operation may be applied in combination with the merged counter trim operation of FIG. 10 and the continuous counter trim operations of FIG. 11.

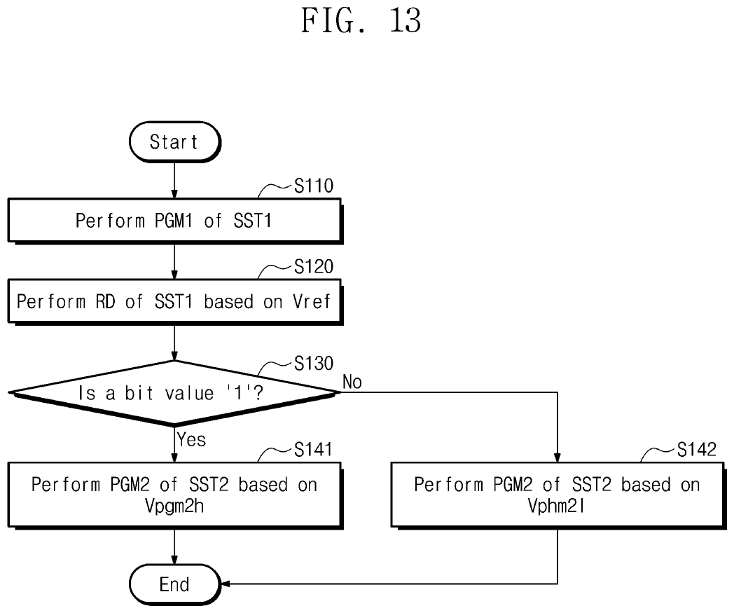

FIG. 13 is a flowchart describing a method of operating a non-volatile memory device according to some embodiments of the present disclosure. Referring to FIG. 13, a non-volatile memory device may include a cell string. The cell string may include the first and second string selection transistors SST1 and SST2.

In operation S110, the non-volatile memory device may perform the first programming operation PGM1 of the first string selection transistor SST1.

In operation S120, the non-volatile memory device may perform the read operation RD of the first string selection transistor SST1 based on the reference voltage Vref. When the reference voltage Vref exceeds the threshold voltage level of the first string selection transistor SST1, a bit value indicating a logical value of “1” may be obtained by the read operation RD. When the reference voltage Vref does not exceed (or, is lower than) the threshold voltage level of the first string selection transistor SST1, a bit value indicating a logical value of “0” may be obtained by the read operation RD.

In operation S130, the non-volatile memory device may determine whether the bit value obtained by the read operation RD indicates the logical value of “1”. In response to determining that the bit value indicates the logical value of “1”, the non-volatile memory device may perform operation S141.

In operation S141, the non-volatile memory device may perform the second programming operation PGM2 of the second string selection transistor SST2 based on the second high programming voltage Vpgm2h. The second string selection transistor SST2 may have the high target threshold voltage level Vtgh.

Returning to operation S130, in response to determining that the bit value does not indicate the logical value of “1”, the non-volatile memory device may perform operation S142.

In operation S142, the non-volatile memory device may perform the second programming operation PGM2 of the second string selection transistor SST2 based on the second low programming voltage Vpgm2l. The second string selection transistor SST2 may have the low target threshold voltage level Vtgl.

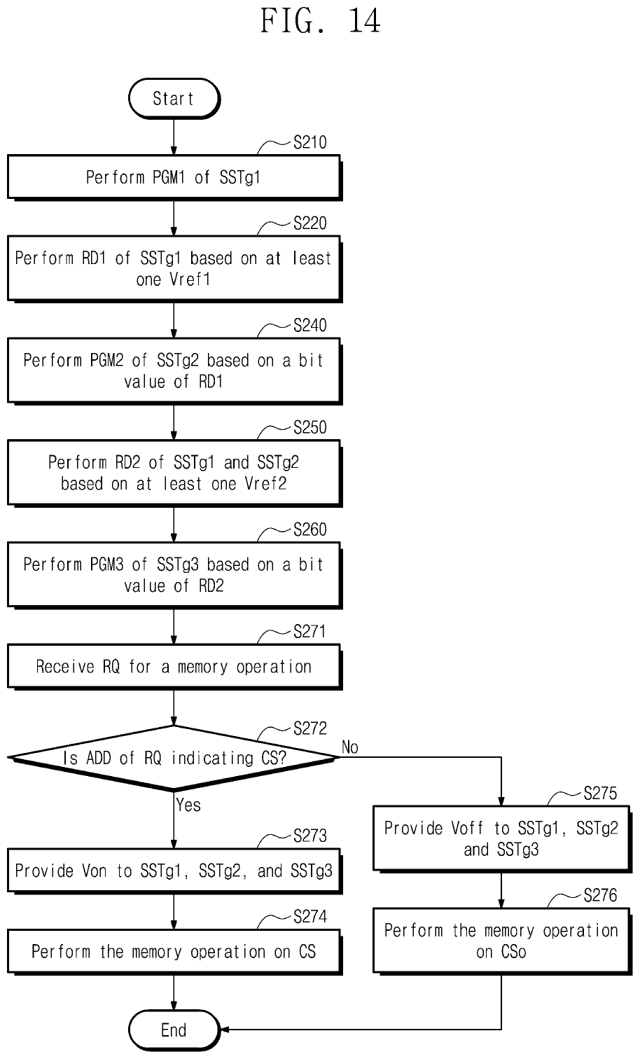

FIG. 14 is a flowchart describing a method of operating a non-volatile memory device according to some embodiments of the present disclosure. Referring to FIG. 14, a non-volatile memory device may include the cell string CS. The cell string CS may include a first group SSTg1, a second group SSTg2, and a third group SSTg3. Each of the first to third groups SSTg1, SSTg2, and SSTg3 may include merged string selection transistors.

In operation S210, the non-volatile memory device may perform the first programming operation PGM1 of the first group SSTg1.

In operation S220, the non-volatile memory device may perform a first read operation RD1 of the first group SSTg1 based on at least one first reference voltage Vref1.

In some embodiments, the non-volatile memory device may support the merged counter trim operation. For example, the first group SSTg1 may include a first string selection transistor and a second string selection transistor. The non-volatile memory device may perform the first programming operation PGM1 by providing the first programming voltage Vpgm1 to the gate terminals of the first and second string selection transistors. The non-volatile memory device may perform the first read operation RD1 by providing at least one first reference voltage Vref1 to the gate terminals of the first and second string selection transistors.

In some embodiments, the non-volatile memory device may support the fine counter trim operation. For example, the non-volatile memory device may divide a threshold voltage level of the first group SSTg1 into four voltage sections. To divide the threshold voltage level into four voltage sections, the non-volatile memory device may use three reference voltages with different voltage levels. In this case, a bit value obtained by the first read operation RD1 may include two bits.

In operation S240, the non-volatile memory device may perform the second programming operation PGM2 of the second group SSTg2 based on the bit value of the first read operation RD1.

In operation S250, the non-volatile memory device may perform a second read operation RD2 of the first group SSTg1 and the second group SSTg2 based on at least one second reference voltage Vref2. For example, to perform the continuous counter trim operation, the non-volatile memory device may handle the first group SSTg1 and the second group SSTg2 as one string selection transistor and may prepare a subsequent counter trim operation for programming the third group SSTg3.

In operation S260, the non-volatile memory device may perform the third programming operation PGM3 of the third group SSTg3 based on the bit value of the second read operation RD2. In detail, in response to that the bit value obtained by the second read operation RD2 indicates the first logical value, the non-volatile memory device may program the threshold voltage level of the third group SSTg3 to a high target threshold voltage level. Alternatively, in response to that the bit value obtained by the second read operation RD2 indicates the second logical value, the non-volatile memory device may program the threshold voltage level of the third group SSTg3 to a low target threshold voltage level.

In operation S271, the non-volatile memory device may receive a request RQ for the memory operation on a memory block including the cell string CS from a storage controller. The memory operation may refer to the read operation or the write operation. The request RQ may include the address ADD.

In operation S272, the non-volatile memory device may determine whether the address ADD of the request RQ indicates the cell string CS. In response to determining that the address ADD of the request RQ indicates the cell string CS, the non-volatile memory device may perform operation S273.

In operation S273, the non-volatile memory device may provide the turn-on voltage Von to the gate terminals of the first to third groups SSTg1, SSTg2, and SSTg3. The first to third groups SSTg1, SSTg2, and SSTg3 may be turned on based on the turn-on voltage Von. The cell string CS may be selected.

In operation S274, the non-volatile memory device may perform the memory operation in the cell string CS, based on that the cell string CS is selected by the turn-on voltage Von.

Returning to operation S272, in response to determining that the address ADD of the request RQ does not indicate the cell string CS, the non-volatile memory device may perform operation S275. In this case, the address ADD may indicate another cell string CSo in the memory block where the cell string CS is included.

In operation S275, the non-volatile memory device may provide the turn-off voltage Voff to the gate terminals of the first to third groups SSTg1, SSTg2, and SSTg3. The first to third groups SSTg1, SSTg2, and SSTg3 may be turned off based on the turn-off voltage Voff. The cell string CS may not be selected.

In operation S276, the non-volatile memory device may perform the memory operation in the cell string CSo of the memory block, based on that the cell string CS is not selected by the turn-off voltage Voff.

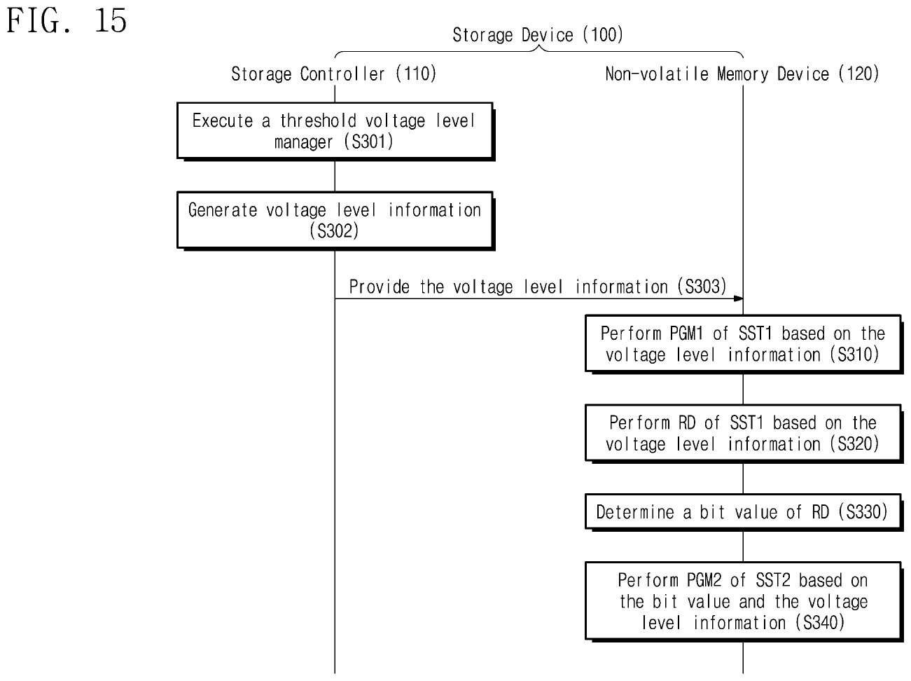

FIG. 15 is a flowchart describing a method of operating a storage device according to some embodiments of the present disclosure. Referring to FIG. 15, the storage device 100 may include the storage controller 110 and the non-volatile memory device 120.

In operation S301, the storage controller 110 may determine a threshold voltage level manager. For example, the threshold voltage level manager may be a firmware module which manages voltage level information.

In operation S302, the storage controller 110 may generate the voltage level information by using the executed threshold voltage level manager. The voltage level information may include information for setting various voltages to be used in the counter trim scheme.

For example, the voltage level information (refer to FIG. 8 together) may be used to determine the first programming voltage Vpgm1 for the first programming operation PGM1 of the first string selection transistor SST1, the reference voltage Vref for determining the threshold voltage level Vth of the first string selection transistor SST1, and the second high programming voltage Vpgm2h and the second low programming voltage Vpgm2l to be used in the second programming operation PGM2 of the second string selection transistor SST2.

In some embodiments, the threshold voltage level manager 111 may optimize the voltage level information based on at least one of a use time of the storage device 100, an operating temperature of the storage device 100, and a power mode of the storage device 100.

In operation S303, the storage controller 110 may provide the voltage level information to the non-volatile memory device. The threshold voltage level management circuit of the non-volatile memory device may be updated based on the voltage level information received from the storage controller 110.

In operation S310, the non-volatile memory device may perform the first programming operation PGM1 of the first string selection transistor SST1 based on the first programming voltage Vpgm1 of the voltage level information.

In operation S320, the non-volatile memory device may perform the read operation RD of the first string selection transistor SST1 based on the reference voltage Vref of the voltage level information.

In operation S330, the non-volatile memory device may determine whether a bit value obtained by the read operation RD indicates the first logical value (e.g., “1”) or the second logical value (e.g., “0”).

In operation S340, the non-volatile memory device may select one of the second high programming voltage Vpgm2h and the second low programming voltage Vpgm2l included in the voltage level information, based on the determined bit value. The non-volatile memory device may perform the second programming operation PGM2 of the second string selection transistor SST2 based on the selected one.

According to an embodiment of the present disclosure, a non-volatile memory device includes a cell string, a storage device including the same, and a method of operating the same are provided.

Also, according to embodiments of the present disclosure, as a programming voltage of a string selection transistor is determined based on a threshold voltage level of an adjacent string selection transistor, the width of a threshold voltage distribution of string selection transistors may decrease. This may mean that a cell string is accurately selected and a driving voltage of the non-volatile memory device decreases.

While the present disclosure has been described with reference to embodiments thereof, it will be apparent to those of ordinary skill in the art that various changes and modifications may be made thereto without departing from the spirit and scope of the present invention as set forth in the following claims.

What is claimed is:

1. A method of operating a non-volatile memory device which includes a first cell string, the method comprising:
performing a programming operation on a first string selection transistor of the first cell string;
performing a first read operation on the first string selection transistor based on a first reference voltage; and
performing a programming operation on a second string selection transistor of the first cell string connected to the first string selection transistor to have:
a first target threshold voltage level in response to that a first bit value obtained by the first read operation indicates a first logical value, and
a second target threshold voltage level lower than the first target threshold voltage level in response to that the first bit value indicates a second logical value opposite to the first logical value.

2. The method of claim 1, wherein the performing of the programming operation on the first string selection transistor of the first cell string includes:
providing a first programming voltage to a gate terminal of the first string selection transistor; and
determining a threshold voltage level of the first string selection transistor, based on the first programming voltage.

3. The method of claim 2, wherein the performing of the first read operation on the first string selection transistor based on the first reference voltage includes:
providing the first reference voltage to the gate terminal of the first string selection transistor;
activating a current channel of the first string selection transistor, based on the first reference voltage exceeding the determined threshold voltage level; and
obtaining the first bit value indicating the first logical value, based on the activated current channel.

4. The method of claim 2, wherein the performing of the first read operation on the first string selection transistor based on the first reference voltage includes:
providing the first reference voltage to the gate terminal of the first string selection transistor;
blocking a current channel of the first string selection transistor, based on the first reference voltage lower than the determined threshold voltage level; and
obtaining the first bit value indicating the second logical value, based on the blocked current channel.

5. The method of claim 1, wherein the first string selection transistor is connected between a bit line and the second string selection transistor.

6. The method of claim 1, wherein the second string selection transistor is connected between a bit line and the first string selection transistor.

7. The method of claim 1, wherein the first cell string includes the first string selection transistor, the second string selection transistor, and a third string selection transistor connected in series.

8. The method of claim 7, wherein the third string selection transistor is connected between a bit line and the first string selection transistor,
wherein the performing of the programming operation on the first string selection transistor of the first cell string includes:
providing a first programming voltage to gate terminals of the first and third string selection transistors, and
wherein the performing of the first read operation on the first string selection transistor based on the first reference voltage includes:
providing the first reference voltage to the gate terminals of the first and third string selection transistors.

9. The method of claim 7, wherein the second string selection transistor is connected between the first string selection transistor and the third string selection transistor, and
wherein the method further comprises:
performing a second read operation on the first string selection transistor and the second string selection transistor based on a second reference voltage; and
performing a programming operation on the third string selection transistor to have:
a third target threshold voltage level in response to that a second bit value obtained by the second read operation indicates the first logical value, and
a fourth target threshold voltage level lower than the third target threshold voltage level in response to that the second bit value indicates the second logical value.

10. The method of claim 1, further comprising:
performing the first read operation on the first string selection transistor based on a second reference voltage and a third reference voltage; and
performing the programming operation on the second string selection transistor to have:
a third target threshold voltage level lower than the second target threshold voltage level in response to that the first bit value obtained by the first read operation indicates a third logical value, and
a fourth target threshold voltage level higher than the first target threshold voltage level in response to that the first bit value indicates a fourth logical value.

11. The method of claim 1, wherein the non-volatile memory device includes a memory block including the first cell string,
wherein the method further comprises:
after performing the programming operation on the second string selection transistor to the first target threshold voltage level or the second target threshold voltage level, receiving a request indicating a memory operation of the memory block from a storage controller,
wherein the memory operation includes a read operation or a write operation of the non-volatile memory device.

12. The method of claim 11, further comprising:
determining whether an address of the request indicates the first cell string;
providing a turn-on voltage to gate terminals of the first and second string selection transistors in response to determining that the address indicates the first cell string; and
performing the memory operation on the first cell string, based on that the first cell string is selected by the turn-on voltage.

13. The method of claim 11, further comprising:
determining whether an address of the request indicates the first cell string;
providing a turn-off voltage to gate terminals of the first and second string selection transistors in response to determining that the address indicates a second cell string of the memory block; and
performing the memory operation on the second cell string, based on that the first cell string is not selected by the turn-off voltage.

14. The method of claim 1, further comprising:
before performing the programming operation on the first string selection transistor, receiving voltage level information from a storage controller,
wherein the voltage level information is used to set:
a first programming voltage for the programming operation on the first string selection transistor,
the first reference voltage,
a second programming voltage corresponding to the first target threshold voltage level, and
a third programming voltage corresponding to the second target threshold voltage level.

15. The method of claim 14, wherein the voltage level information is determined based on at least one of a use time of a storage device including the non-volatile memory device, a temperature of the storage device, and a power mode of the storage device.

16. A non-volatile memory device comprising:
a cell string including a first string selection transistor and a second string selection transistor connected in series;
a voltage generating circuit connected to the first string selection transistor through a first string selection line and connected to the second string selection transistor through a second string selection line;
a page buffer circuit connected to the cell string through a bit line; and
a threshold voltage level management circuit configured to:
provide a first programming voltage to the first string selection transistor through the voltage generation circuit,
provide a reference voltage to the first string selection transistor through the voltage generation circuit,
receive a bit value of the first string selection transistor corresponding to the reference voltage from the page buffer circuit,
provide a second programming voltage to the second string selection transistor through the voltage generation circuit in response to that the bit value indicates a first logical value, and
provide a third programming voltage lower than the second programming voltage to the second string selection transistor through the voltage generation circuit in response to that the bit value indicates a second logical value opposite to the first logical value.

17. The non-volatile memory device of claim 16, wherein the first string selection transistor has a threshold voltage level determined based on the first programming voltage, and
wherein the first string selection transistor is configured to:
provide a first electrical signal corresponding to the first logical value to the page buffer circuit, based on the reference voltage exceeding the threshold voltage level of the first string selection transistor, and
provide a second electrical signal corresponding to the second logical value to the page buffer circuit, based on the reference voltage lower than the threshold voltage level of the first string selection transistor.

18. A storage device comprising:
a storage controller configured to generate voltage level information including a reference voltage, a first programming voltage, a second programming voltage, and a third programming voltage; and
a non-volatile memory device including a first cell string, and configured to:
receive the voltage level information from the storage controller,
perform a programming operation on a first string selection transistor of the first cell string, based on the first programming voltage,
perform a read operation on the first string selection transistor, based on the reference voltage, and
perform a programming operation on a second string selection transistor of the first cell string to have:
a first target threshold voltage level in response to that a bit value obtained by the read operation indicates a first logical value, based on the second programming voltage, and
a second target threshold voltage level lower than the first target threshold voltage level in response to that the bit value indicates a second logical value opposite to the first logical value, based on the third programming voltage.

19. The storage device of claim 18, wherein the storage controller is further configured to determine the voltage level information based on at least one of a use time of the storage device, an operating temperature of the storage device, and a power mode of the storage device.

20. The storage device of claim 18, wherein the non-volatile memory device further includes a memory block including the first cell string,
wherein the storage controller is further configured to provide a request indicating a memory operation on the memory block to the non-volatile memory device,
wherein the non-volatile memory device is further configured to:
determine whether an address of the request indicates the first cell string,
perform the memory operation on the first cell string in response to determining that the address indicates the first cell string, and
perform the memory operation on a second cell string of the memory block in response to determining that the address indicates the second cell string, and
wherein the memory operation includes a read operation or a write operation of the non-volatile memory device.
